(19) United States
(12) Patent Application Publication
(10) Pub. No.: US 2013/0328155 A1
(43) Pub. Date: Dec. 12, 2013

(54) GENERATION OF ADDITIONAL SHAPES ON A PHOTOMASK FOR A MULTIPLE EXPOSURE PROCESS

(71) Applicant: Kenji Konomi, Junction, NY (US)

(72) Inventor: Kenji Konomi, Junction, NY (US)

(73) Assignee: TOSHIBA AMERICA ELECTRONIC COMPONENTS, INC., Irvine, CA (US)

(21) Appl. No.: 13/490,646

(22) Filed: Jun. 7, 2012

(51) Int. Cl. G06F 17/50; H01L 21/32; H01L 29/02

(52) U.S. Cl. 257/499; 716/52; 716/50; 438/694; 257/E29.002; 257/E21.258

(57) ABSTRACT

The disclosed aspects relate to controlling density of photomasks. One or more unprintable auxiliary patterns can be placed near a mask feature as well as onto a location of a feature of the main pattern. If a density is measured and is not within an acceptable density range, one or more printable auxiliary patterns can be replaced with unprintable auxiliary patterns and/or one or more unprintable auxiliary patterns can be replaced with printable auxiliary patterns. The disclosed aspects can be utilized to create a photomask and/or a semiconductor device, such as a large scale integrated circuit device, that comprises the photomask.

### FIELD

The following description relates generally to controlling mask density through the generation of additional shapes on a photomask for a multiple exposure process.

### BACKGROUND

Silicon large-scale integrated circuits, among other device technologies, are escalating in use in order to accommodate the advanced information society of today and of the future. An integrated circuit may be composed of a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged.

To manufacture such semiconductor devices, in some cases the minimum size of the features of the chips are continuing to decrease. For example, in some semiconductor devices, patterns that have a pitch less than 80 nm (<80 nm) are printed on the wafer. However, in some cases, the pattern might have a pitch that is more than 80 nm (>80 nm). To simplify and minimize the complexity of the design, the final wafer images can be decomposed into several different layers and patterns during the mask data preparation. For example, the design layout can be split into two or more photomasks in the lithography process to print one layer of a semiconductor process. In other words, even the most advanced lithography process cannot print patterns having a pitch <80 nm using a single photomask. When the design layout is split into the two or more photomasks the pattern density of one or more of the photomasks might not be within an acceptable level due to the splitting process.

The above-described deficiencies of today's semiconductor manufacturing processes and solutions are merely intended to provide an overview of some of the problems of conventional systems, and are not intended to be exhaustive. Other problems with conventional systems and corresponding benefits of the various non-limiting embodiments described herein may become further apparent upon review of the following description.

### BRIEF DESCRIPTION OF THE DRAWINGS

FIG. 1 illustrates an example of a design layout that can be divided into two or more photomasks.

FIG. 2 illustrates the example design layout of FIG. 1 that includes additional patterns that can be used to provide appropriate pattern density.

FIG. 3 illustrates a non-limiting system configured to generate additional shapes on a photomask for a multiple exposure process, according to an aspect.

FIG. 4 illustrates example photomasks for the pattern layout of FIG. 1, according to an aspect.

FIG. 5 illustrates a non-limiting system for generation of photomasks having a uniform (or near uniform) density, according to an aspect.

FIG. 6 illustrates an example photomask for which a density calculation of a first subset is determined, according to an aspect.

FIG. 7 illustrates the example photomask of FIG. 6 for which a density calculation of a second subset is determined, according to an aspect.

FIG. 8 illustrates the example photomask of FIG. 6 for which a density calculation of a third subset is determined, according to an aspect.

FIG. 9 illustrates a non-limiting example method for the generation of additional shapes on a photomask for a multiple exposure process, according to an aspect.

FIG. 10 illustrates another non-limiting example method for the generation of additional shapes on a photomask for a multiple exposure process, according to an aspect.

FIG. 11 illustrates a further non-limiting example method for the generation of additional shapes on a photomask for a multiple exposure process, according to an aspect.

FIG. 12 is a block diagram illustrating an example computing device that is arranged for at least some of the embodiments disclosed herein.

### DETAILED DESCRIPTION

The embodiments disclosed herein provide various techniques related to semiconductor manufacturing processes and solutions. In particular, the aspects disclosed herein relate to controlling mask density through the generation of additional shapes on a photomask for a multiple exposure process.

As discussed in the background, in some cases, a design layout is split into at least two photomasks in the lithography process to print one layer of a semiconductor process. For example, a computer program can be used to check the chip design shape and to split the chip design into two or more masks that have data without an unprintable pattern due to too narrow pitch or space. Then, another program generates dummy (or auxiliary) shapes to fill a large vacant area with the shapes. A problem associated with splitting the design layout is that the pattern density might be different (sometimes very different) between the two or more masks. When the density is different in a local area on the mask, the Critical Dimension (CD) uniformity can become inferior in quality. Although dummy patterns (also referred to as additional patterns or auxiliary patterns) can be located to retain the density of a layout, the dummy patterns must be also be split in the multi-mask process, which can create areas that have insufficient density and/or areas that do not have a pattern (e.g., vacant areas).

In accordance with some aspects, a program is utilized that employs an algorithm to verify the chip design shapes on data for other masks as a special area. The unprintable dummy shapes can be placed on the special areas of the mask. Further, the program can check the printable dummy shapes generated on data for other masks and can place unprintable dummy shapes on the overlap area. Additionally, the program can calculate the pattern density, including dummy shapes, for each mask. As a result of the calculation, the dummy shapes can be relocated, as necessary, to retain a desired density for each of the split masks. According to some aspects, one or more unprintable masks can be replaced with printable masks and/or one or more printable masks can be replaced with unprintable masks.

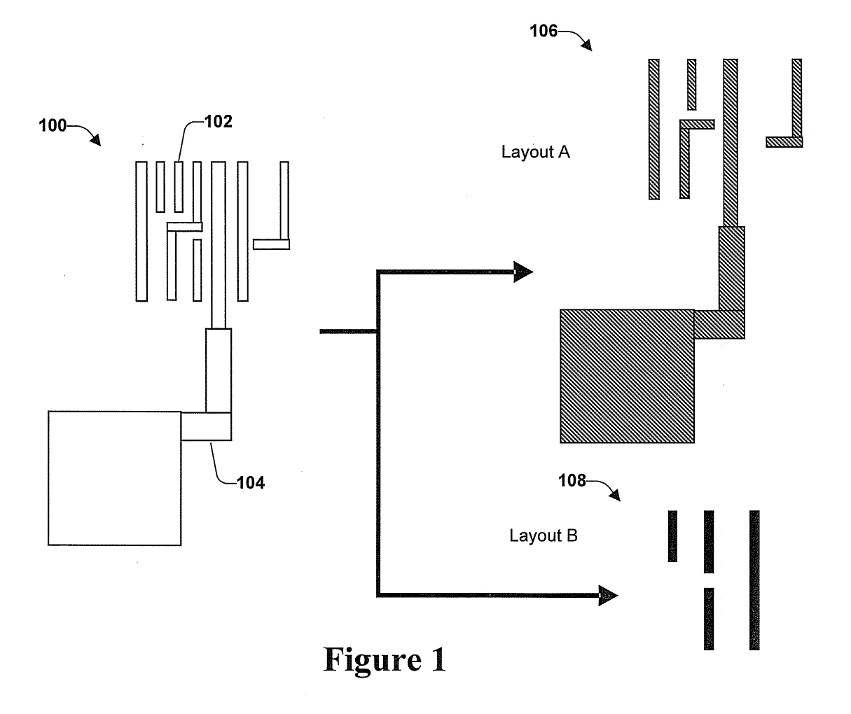

FIG. 1 illustrates an example of a design layout that can be divided into two or more photomasks. A wafer processing procedure can include various steps including depositing a wiring layer on the wafer. The wiring layer and/or other layers (e.g., insulating layer, polysilicon layer, and so forth) can be formed in patterns that are designated by design data. For example, the design data can result in the example design pattern 100 of FIG. 1. It should be noted that the disclosed aspects are not limited to the illustrated design pattern 100 and a multitude of other design patterns can be utilized with the aspects disclosed herein. The design pattern 100 is a representation of the designer's intended layout or wafer layout. The design pattern 100 can comprise a multitude of pattern lines 102, 104 (only two of which are labeled), which are arranged according to the design data. The design pattern or wafer layout can contain numerous features that together make up the semiconductor. These features can be divided into sections, which can be variable in size and/or shape. There can be any combination of sections possible, depending on the semiconductor being printed.

In some cases, two or more photomasks might be used to create a single chip pattern (e.g., design pattern 100) on a wafer. For example, the design pattern 100 can be divided into two (or more) layouts. In the example of FIG. 1, the design pattern 100 is divided into two layouts, labeled as Layout A 106 and Layout B 108. The portions or layouts can be of any size in relation to the wafer layouts.

Due to the nature of depositing an insulating layer and wiring layer, for example, a height difference between portions of the surface that comprise patterns lines and other portions of the surface in which no pattern lines exist can be formed in the layouts. The allowable height difference can be directly proportional to the progressive miniaturization of patterns formed on the layers. Thus, there might be locations on the layouts that do not conform to the allowable height difference (e.g., are out of specification); therefore additional patterns (e.g., dummy patterns) can be utilized.

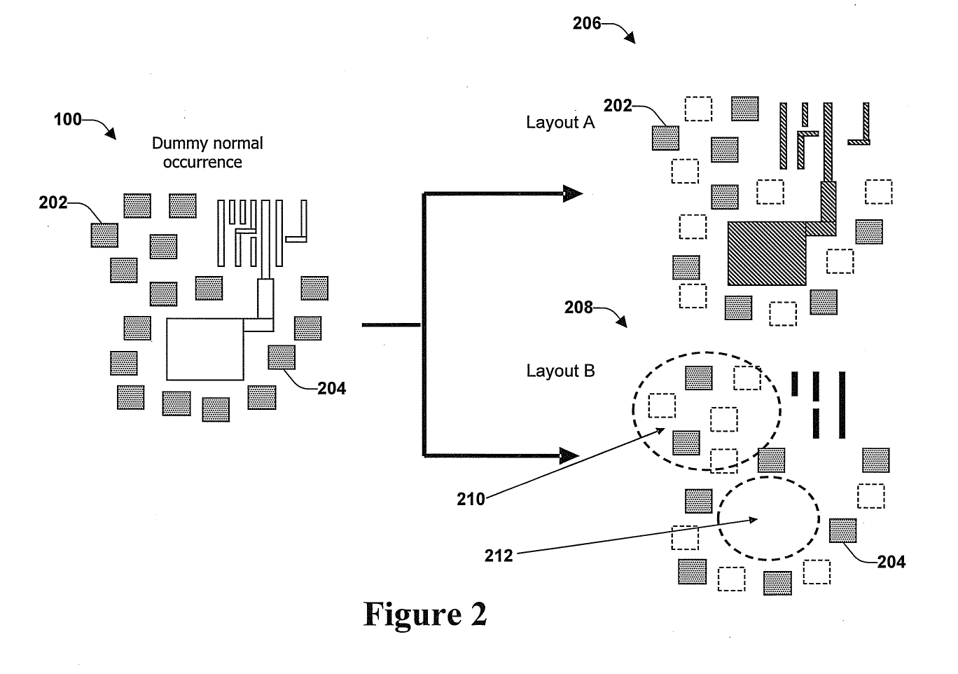

FIG. 2 illustrates the example design layout of FIG. 1 that includes additional patterns that can be used to provide appropriate pattern density. Illustrated is the design pattern 100 (e.g., a chip design) and additional patterns 202, 204 (only a few of which are labeled) for a single mask. The additional patterns 202 (sometimes referred to as “dummy patterns” or “auxiliary patterns”) are utilized for forming pattern elements that do not participate in forming a circuit. Generally, the additional patterns 202, 204 are placed around the main features of the layout of the design pattern 100. The additional patterns 202, 204 can be generated to control density of the mask, for example.

In a double patterning process, the additional patterns 202, 204 can be split into two (or more) sets of additional patterns. For example, the auxiliary patterns can be divided, as illustrated in Layout A 206 and Layout B 208. For example, several multiple exposure processes are necessary in 22 nm node or later technologies. In the process, two or more photomasks are used to create one chip pattern on a wafer. To create the chip pattern with the desired critical dimension variation, dummy shapes (e.g., additional patterns) are placed to keep a certain density of pattern, for both the photomask and wafer. However, since the multiple exposure process has to split the additional patterns onto each mask, it can result in each mask having a lower density or large area with lack of a dummy shape.

In some cases, after the additional patterns are split, vacant areas 210, 212 (illustrated within the dashed circles) might be formed. For example, vacant area 210 illustrates an area with an insufficient density (e.g., lower density) and vacant area 212 (e.g., (large) area with lack of additional patterns) illustrates an overlap area to the chip pattern on mask A (or Layout A 206).

The vacant areas 210, 212 (as well as other areas) can create density areas between Layout A 206 and Layout B 208 that are different, which can result in variations in the pattern density. Such variations in the pattern density can result in each mask (e.g., Layout A 206 and Layout B 208) having a lower density than is acceptable and/or a large area with the lack of an additional pattern (e.g., a vacant area). For example, if one or more masks (e.g., Layouts) has a low (or very low) or a high (or very high) density, the CD can be difficult to control for that mask. The disclosed aspects can overcome the CD control problems associated with traditional semiconductor manufacturing processes by placement of additional auxiliary patterns, which can be unprintable auxiliary patterns according to an aspect.

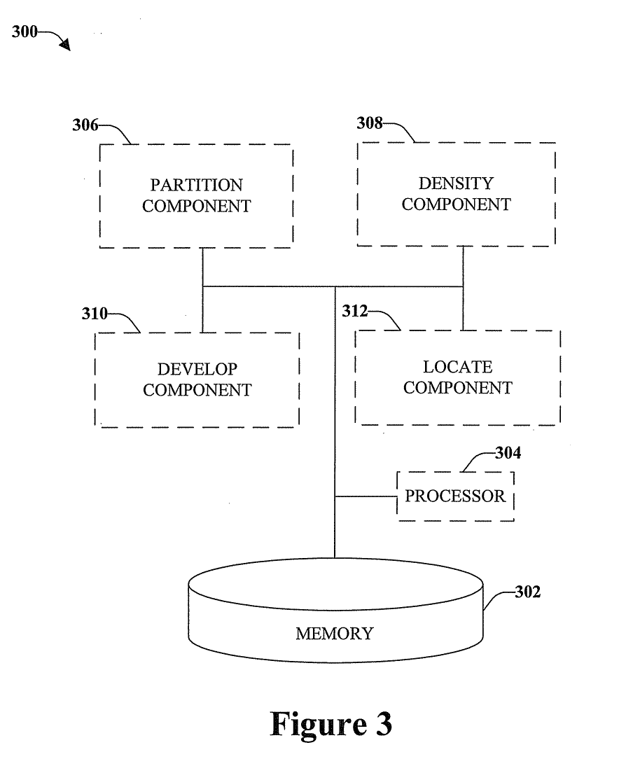

FIG. 3 illustrates a non-limiting system 300 configured to generate additional shapes on a photomask for a multiple exposure process, according to an aspect. The disclosed aspects can overcome the above-described deficiencies of conventional manufacturing processes by generating and placing unprintable additional patterns on each photomask. For example, two small dummy features (e.g., additional patterns) can be created to print on a wafer into each of the photomasks. Calculations can be performed to analyze the chip pattern on each photomask and determine the proper area to place the unprintable dummy features (or additional patterns). In an implementation, a photomask can be prepared according to the disclosed aspects. In another implementation, a semiconductor device can be prepared using a photomask prepared according to the disclosed aspects. In yet another implementation, the semiconductor device can be a large scale integrated circuit (LSI) device.

Various aspects of the systems, apparatuses, and/or processes explained in this disclosure can constitute machine-executable components embodied within one or more machines, such as, for example, embodied in one or more computer readable mediums (or media) associated with one or more machines. Such component(s), when executed by the one or more machines (e.g., computer(s), computing device(s), virtual machine(s), and so on) can cause the machine(s) to perform the operations described.

System 300 can include a memory 302 that stores computer executable components and instructions. System 300 can also include a processor 304 that executes computer executable components stored in the memory 302. It should be noted that although one or more computer executable components may be described herein and illustrated as components separate from memory 302, in accordance with various aspects, the one or more computer executable components can be stored in memory 302.

System 300 also includes a partition component 306 configured to prepare photomasks from layouts. For example, partition component 306 can be configured to divide an original pattern layout into two or more photomasks. Schematics and images can be drawn on a single layer (e.g., pattern layout) in order to simplify the design process for the designers. To create semiconductors at 20 nm and beyond, the layouts can be decomposed into multiple photomasks to create features that are smaller than the wavelength of the light being used. Pitch splitting processes, such as Sidewall Image Transfer (SIT), can be used to achieve 20 nm and smaller technology nodes where single exposure lithography becomes inoperable. The photomasks used in SIT are, therefore, decomposed from the single layer design layouts (e.g., layout pattern).

Also included in system 300 is a density component 308 that is configured to calculate the layout density of the layout pattern. In accordance with some aspects, the pattern density calculation includes the auxiliary patterns for each mask. For example, density component 308 can evaluate a first section of the layout pattern and calculate the density of the first section. The density calculation can be retained (e.g., by density component 308, in memory 302, and so forth). After calculating the first density, a second section of the layout pattern can be evaluated by density component 308 in order to calculate the density of the second section. In accordance with some aspects, the second section overlaps at least a portion of the first section. The calculation of the density of the second section can be retained (e.g., by density component 308, in memory 302, and so forth). Density component 308 can evaluate a third section, which can overlap at least a portion of the second section, and calculate a density of the third section. This process can continue until all sections of the pattern layout (e.g., the entirety of the pattern layout) are evaluated by density component 308. The calculation of each section is performed independently of each of the other sections. Further details related to the density calculation will be provided below.

Based on the calculations made by density component 308, a develop component 310 can be configured to generate one or more auxiliary patterns within one or more sections of each photomask. A locate component 312 can be configured to selectively place the one or more auxiliary patterns at a location on a photomask to create a photomask having a desired pattern density.

For example, if the density component 308 performs a calculation and determines that the density of the third section is below (or above) an acceptable range, the locate component 312 can place one or more auxiliary patterns within the third section (or remove one or more auxiliary patterns from the third section) such that the density of the section is within the acceptable range. In accordance with some aspects, after the develop component 310 generates and the locate component 312 places the auxiliary pattern(s), the density component 308 performs another calculation to determine if the density of the section is within the acceptable range. Further actions can be performed by develop component 310 and/or locate component 312 (e.g., remove one or more auxiliary patterns, place one or more auxiliary patterns within the section, and so forth), until it is determined by density component 308 that the density of the section is within the acceptable range.

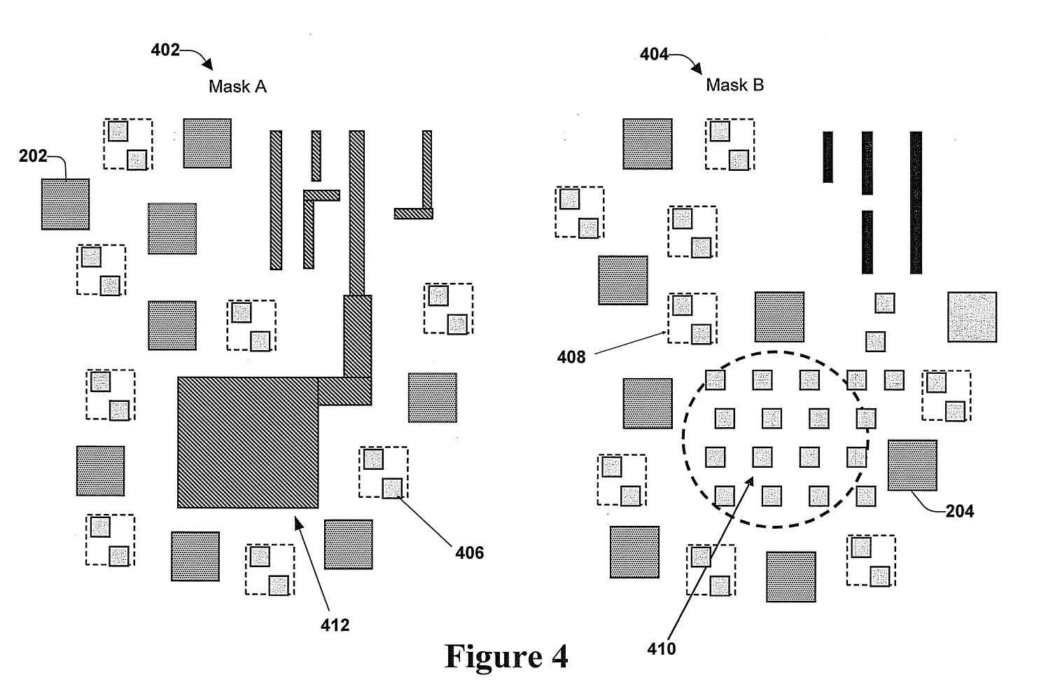

FIG. 4 illustrates example photomasks for the pattern layout of FIG. 1, according to an aspect. The mask for Layout A is illustrated by the first mask 402 and the mask for Layout B is illustrated by the second mask 404. Unprintable auxiliary patterns can be generated (e.g., by develop component 310) in accordance with the disclosed aspects. As illustrated in the first mask 402, two small unprintable dummies or additional patterns 406 (only one of which is labeled) can be used to brace the original pattern for mask control.

For example, additional patterns 202, 204 can be generated (e.g., by develop component 310) to control density of the mask. However, there are various areas on the masks that might not conform to a pattern density and, therefore, additional patterns can be placed around the original pattern and, in some cases, can be placed around the original additional patterns 202, 204.

It should be noted that the unprintable auxiliary patterns illustrated in FIG. 4 are for example purposes only. In some aspects, any number of unprintable additional patterns can be used to brace the original pattern for mask control. Additionally or alternatively, in some aspects, the one or more additional patterns can be various sizes and/or shapes. Further, in the case where two or more additional patterns are utilized, each of the additional patterns can have the same or different sizes and/or shapes.

As illustrated by the second mask 404, several unprintable additional patterns 408 (only one of which is labeled) can be placed onto the location of the major feature of the main pattern, which corresponds with the main feature 410 of the first mask 402 in this example.

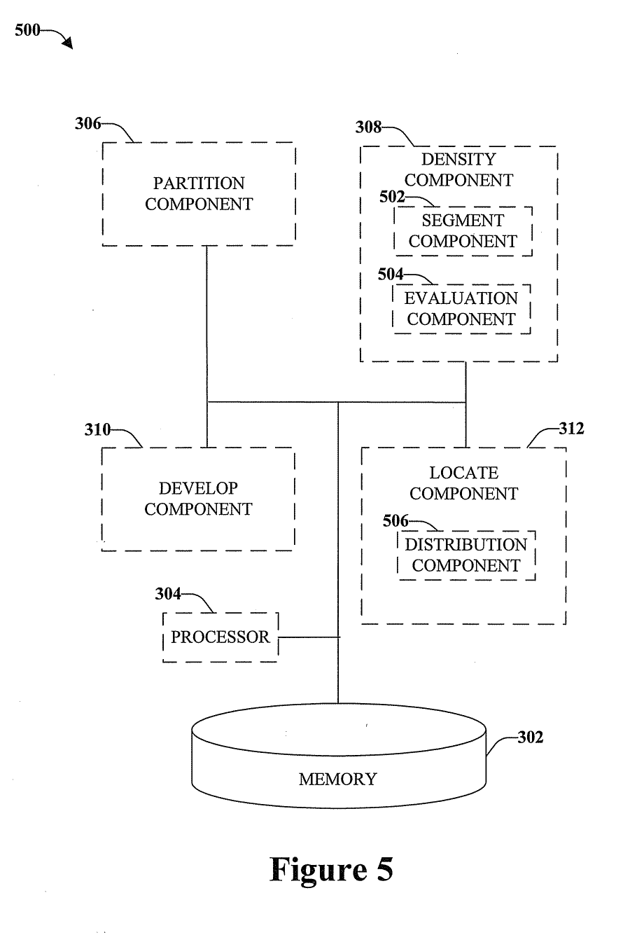

FIG. 5 illustrates a non-limiting system 500 for generation of photomasks having a uniform (or near uniform) density, according to an aspect. Included in system 500 is a partition component 306 that is configured to divide a design layout into a first mask and at least a second mask. A density component 308 is configured to calculate a layout density of the first mask and the at least a second mask. A develop component 310 is configured to, based on the calculation performed by the density component 308, generate at least one unprintable auxiliary pattern. A locate component 312 is configured to place the at least one unprintable auxiliary pattern on the first mask as a result of the calculation performed by the density component 308 (e.g., to select an appropriate area of the first mask were the unprintable auxiliary pattern should be placed). In accordance with some aspects, the at least one unprintable auxiliary pattern overlaps a main area of the second mask.

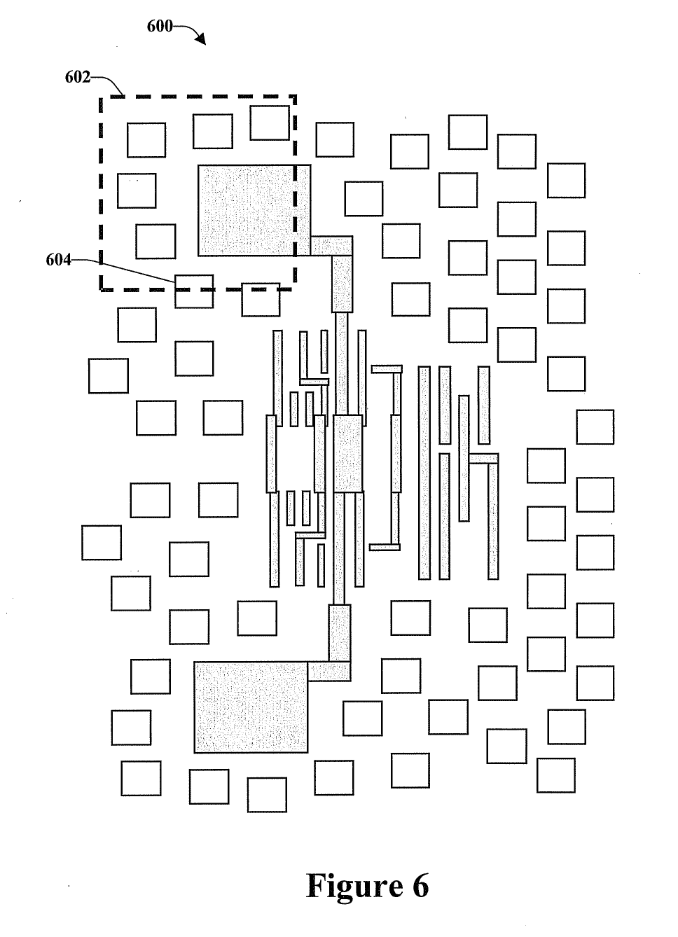

In an implementation, density component 308 can include a segment component 502 that divides a photomask into various portions (e.g., subsets or sections). For example, FIG. 6 illustrates an example photomask 600 for which a density calculation of a first subset is determined (e.g., by a segment component), according to an aspect. The layout pattern is illustrated by the filled boxes and the auxiliary patterns are illustrated by the unfilled boxes.

With continuing reference to FIGS. 5 and 6, the segment component 502 can create a first subset 602, which can be a portion of the entire example photomask 600. As illustrated, the first subset 602 (as well as subsequent subsets) can comprise at least a portion of the layout pattern and/or at least a portion of the auxiliary patterns. Further, the portion(s) of the layout pattern and/or the portion(s) of the auxiliary patterns do not need to be entire portions thereof, (e.g., one or more auxiliary patterns can be split, one or more layout patterns can be split), as illustrated by auxiliary pattern 604. The size of the first subset 602 (and subsequent subsets) can be determined based on various considerations including, for example, the process, the type of photomask, the acceptable specifications or tolerances associated with the photomask, and so forth.

The density component 308 can also include an evaluation component 504 configured to calculate the density of the first subset 602 (and subsequent subsets). For example, the calculation by evaluation component 504 can be made by preparing a test mask that includes patterns with the density variation. The mask can be exposed to photo resist coating on the substrate and the substrate can be etched. The evaluation component 504 can then measure how much the impact is to the pattern sizes and the topography. Then, the specification to be accepted based on various assumptions of the device can be made.

A distribution component 506 can be configured to place one or more auxiliary patterns within the first subset 602, based on the calculation performed by the evaluation component 504. For example, the calculation might indicate that the density is not within an acceptable range but can be corrected by placing one or more unprintable auxiliary patterns within the first subset 602. In accordance with some aspects, the distribution component 506 can be configured to remove one or more auxiliary patterns based on the calculation by the evaluation component 504. For example, the calculation by evaluation component 504 might indicate that the density is outside of the acceptable range and, to bring the density within the acceptable range, one or more unprintable auxiliary patterns should be removed. In an exemplary, non-limiting example, an acceptable density might be 20<, 50% in 1×1 um.

In some implementations, when auxiliary patterns are added and/or removed to the first subset 602 (and/or subsequent subsets), the evaluation component 504 can be configured to perform another calculation to determine the density. If the density is still not within an acceptable range, the distribution component 506 can add (or remove) one or more auxiliary patterns and, thereafter, another calculation can be performed by evaluation component 504. This process can be recursive such that any number of calculations are performed by evaluation component 504 and/or any number of changes (e.g., adding or removing one or more auxiliary patterns) are facilitated by distribution component 506.

In accordance with some aspects, the distribution component 506 can be configured to locate one or more auxiliary patterns into a larger space on the first mask, for example. Density component 308 can be configured to recalculate the density of the first mask. Based on the recalculation, the develop component 310 can be configured to modify one or more attributes of the at least one unprintable auxiliary patterns. For example, modifying the one or more attributes can include changing a location of one or more unprintable auxiliary pattern, replacing one or more unprintable auxiliary patterns with one or more printable auxiliary patterns, and/or replacing one or more printable auxiliary patterns with one or more unprintable auxiliary patterns.

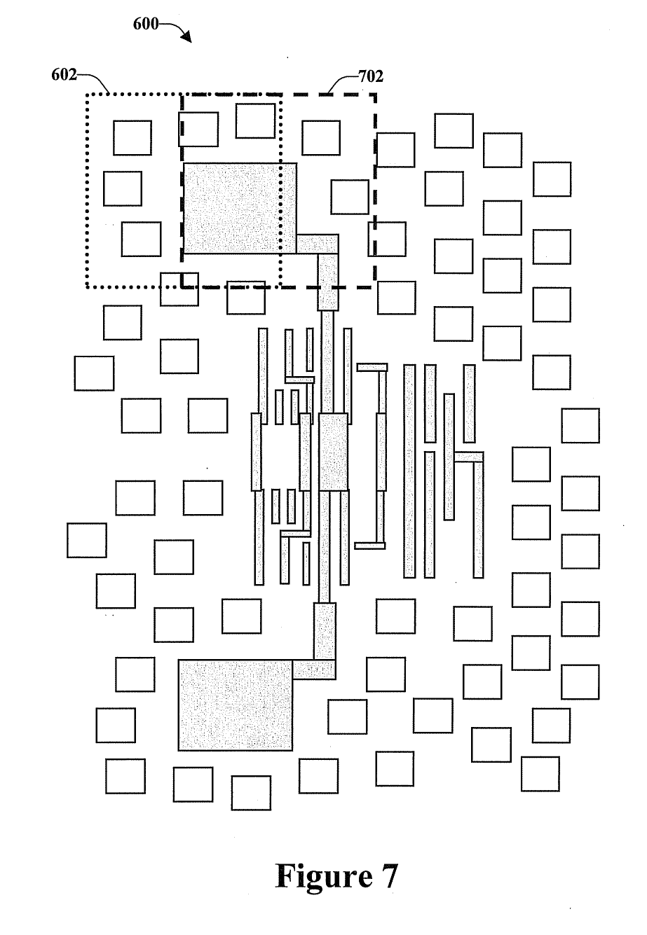

With reference also to FIG. 7, after the first subset 602 has been evaluated, a second subset 702 is evaluated. FIG. 7 illustrates the example photomask 600 for which a density calculation of a second subset 702 is determined, according to an aspect. As illustrated, the box area of the first subset 602 is shifted (e.g., in this example to the right) to create a second subset 702. Although illustrated and described as a “box area”, the geometric shape of the subsets do not need to be box shaped. For example, the evaluation area that forms each subset can be any type of geometric shape that is generally composed of straight line segments or that is generally composed of curved line segments or combinations thereof.

In accordance with some aspects, the shift amount can be about half the size of the shape area. For example, as illustrated, the shift amount is about half of the box size. According to some aspects, the shift amount can be equal (or almost equal) to the shape size. For example, in one implementation the shift amount can be such that the second subset does not overlap the first subset. In another implementation, the shift amount can be such that subsequent shape areas at least partially overlap a preceding shape area.

Further, although the shift amount is shown as shifting to the right, the disclosed aspects are not limited to this shift amount and/or direction. For example, the shift can be in a downward direction, in an upward direction, in a direction to the right, in a direction to the left, or in other directions, such as diagonally (e.g., downward and to the left, upward and to the left, and so forth).

The evaluation component 504 is configured to calculate the density of the second subset 702, similar to the manner in which the evaluation component 504 calculates the density of the first subset 602. In a similar manner to that described above, the distribution component 506 selective adds or removes (to the second subset 702) one or more auxiliary patterns as a result of the calculation performed by evaluation component 504.

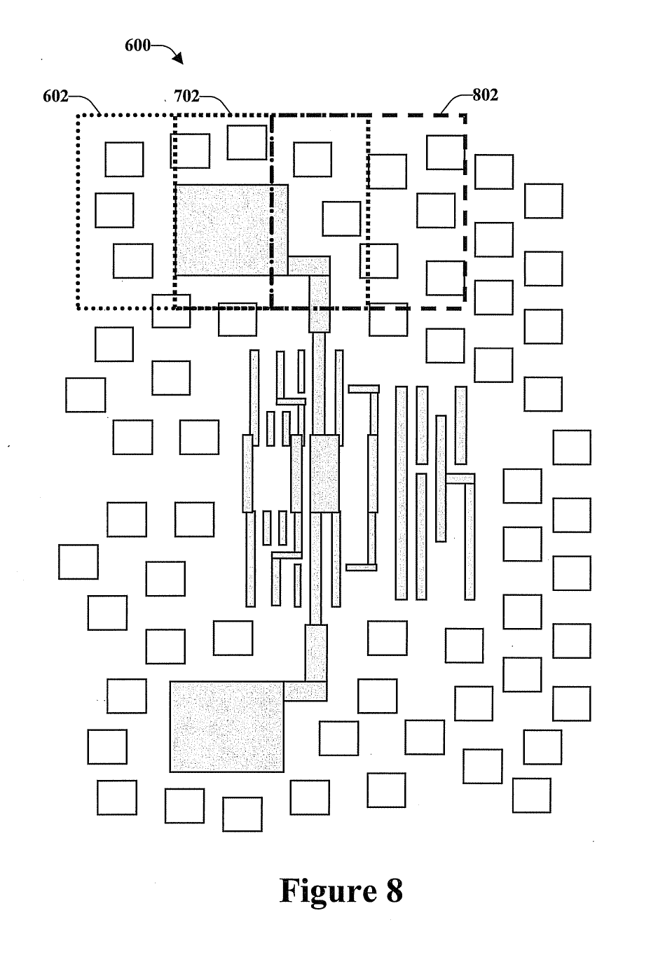

Continuing the above example, FIG. 8 illustrates the example photomask 600 for which a density calculation of a third subset 802 is determined, according to an aspect. As illustrated, the box area (or other geometric area) is shifted to a subsequent subset (e.g., third subset 802). A calculation of the subsequent subset is performed by evaluation component 504. If needed, further adjustments (e.g., adding one or more unprintable auxiliary patterns, removing one or more auxiliary patterns, changing an unprintable pattern to a printable pattern, changing a printable pattern to an unprintable pattern, and so forth) are made by distribution component 506. Similar shifts to the geometric area, calculations, and adjustments are made for subsequent subsets until the entire photomask 600 has been considered and appropriate modifications (e.g., addition and/or removal of one or more auxiliary patterns) have been performed.

Methods that may be implemented in accordance with the disclosed subject matter will be better appreciated with reference to the following flow charts. While, for purposes of simplicity of explanation, the methods are shown and described as a series of blocks, it is to be understood and appreciated that the disclosed aspects are not limited by the number or order of blocks, as some blocks may occur in different orders and/or at substantially the same time with other blocks from what is depicted and described herein. Moreover, not all illustrated blocks may be required to implement the disclosed methods.

It is to be appreciated that the functionality associated with the blocks may be implemented by software, hardware, a combination thereof, or any other suitable means (e.g. device, system, process, component, and so forth). Additionally, it should be further appreciated that the disclosed methods are capable of being stored on an article of manufacture to facilitate transporting and transferring such methods to various devices.

Those skilled in the art will understand and appreciate that methods could alternatively be represented as a series of interrelated states or events, such as in a state diagram. In an implementation, the methods disclosed herein use a processor to execute computer executable components stored in a memory.

Further, the various aspects disclosed herein can be utilized to prepare a photomask and/or a semiconductor device comprising the photomask. In an example, the semiconductor device can be a large scale integrated circuit (LSI) device.

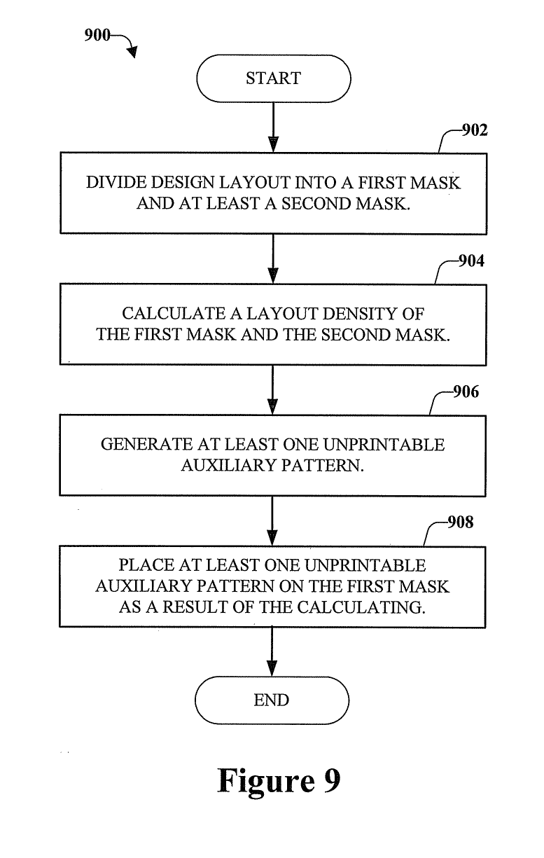

FIG. 9 illustrates a non-limiting example method 900 for the generation of additional shapes on a photomask for a multiple exposure process, according to an aspect. Method 900 starts, at 902, by dividing a design layout into a first mask and at least a second mask. As discussed herein, several multiple exposure processes might be necessary in 22 nm node or later technologies. In the process, two or more photomasks can be used to create a single chip pattern on a wafer.

Layout density of the first mask and the second mask is calculated, at 904. The calculation can take into consideration auxiliary patterns placed on each mask during the splitting process. Due to the nature of dividing the design layout into two or more photomasks, the density of each of the photomasks might not be at an acceptable level. In accordance with some aspects, the layout density can be calculated at the end of a process after the density specification is ascertained. However, the disclosed aspects are not so limited and, according to some aspects, one or more iterations might be utilized to confirm a density specification and/or adherence to the density specification.

At 906, at least one unprintable auxiliary pattern is generated. In an implementation, generating the at least one unprintable auxiliary pattern comprises generating two or more unprintable auxiliary patterns. The two or more unprintable auxiliary patterns can be a different size, a different shape, or both a different size and a different shape. In another implementation, generating the at least one unprintable auxiliary pattern comprises generating two or more unprintable auxiliary patterns. The two or more unprintable auxiliary patterns can comprise a similar size, a similar shape, or a similar size and a similar shape.

At 908, the at least one unprintable auxiliary pattern is placed on the first mask as a result of the calculating. The at least one unprintable auxiliary pattern can overlap a main area of the second mask. To create the chip pattern with the appropriate critical dimension variation, dummy shapes (e.g., auxiliary patterns) are placed to keep a certain density of pattern, for both photomask and wafer. However, the multiple exposure process has to split the dummy shapes onto each mask, which means each mask has a lower density or large area with lack of dummy shapes, which can result in a pattern density that is out of tolerance or out of specification. The disclosed aspects overcome the aforementioned challenges by placing unprintable dummy features into each of the photomasks.

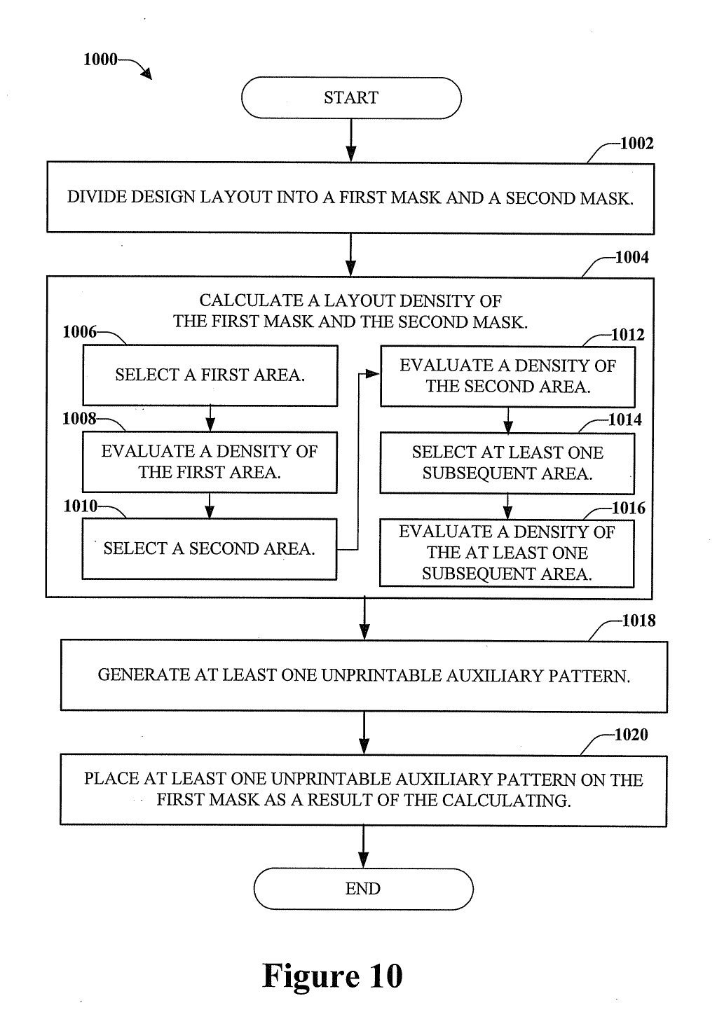

FIG. 10 illustrates another non-limiting example method for the generation of additional shapes on a photomask for a multiple exposure process, according to an aspect. Method starts, at 1002, when a design layout is divided into a first mask and at least a second mask. In an implementation, the design layout can be divided into any number of masks.

At 1004, a layout density of the first mask and at least the second mask is calculated. The calculating can include, selecting a first area of the design layout, at 1006. The first area is a portion of the entire mask (e.g., less than 100% of the mask). Included in the first area (as well as subsequent areas) can be a portion of the layout pattern, a portion of the auxiliary patterns, and/or portions thereof. The first area (and subsequent areas can be generally composed of straight line segments, generally composed of curved line segments, or combinations thereof. Further, the first area (and subsequent areas) can be any size and/or shape.

At 1008, a density of the first area is evaluated. The evaluation can include calculating the density of the first area. In an example, the evaluation can determine whether a calculated density is within an acceptable range.

The calculating can also include, after selection and evaluation of the first area, selection of a second area, at 1010. The second area can be approximately the same size and/or shape of the first area. In an aspect, the second area can include at least a portion of the first area. In accordance with some aspects, selecting the second area can comprise shifting from the first area to a location that is offset from the first area by at least a portion of the first area. In an implementation, the portion can be about half the size of the first area. At 1012, a density of the second area is evaluated, similar to the manner in which the first area is evaluated.

Also included in the calculating is selection of a subsequent area, at 1014. For example, the subsequent area can be any one of a number of areas of the mask that are needed to be evaluated such that the entire mask is evaluated. It should be noted that the subsequent areas can be about the same size and/or shape as the first area and the second area. At 1016, a density of the at least one subsequent area is evaluated as discussed herein.

At 1018, at least one unprintable auxiliary pattern is generated and placed, at 1020, on the first mask. The generation and placement of the at least one unprintable auxiliary pattern is based, in part, on the evaluations of the first area, the second area, and/or the subsequent area(s).

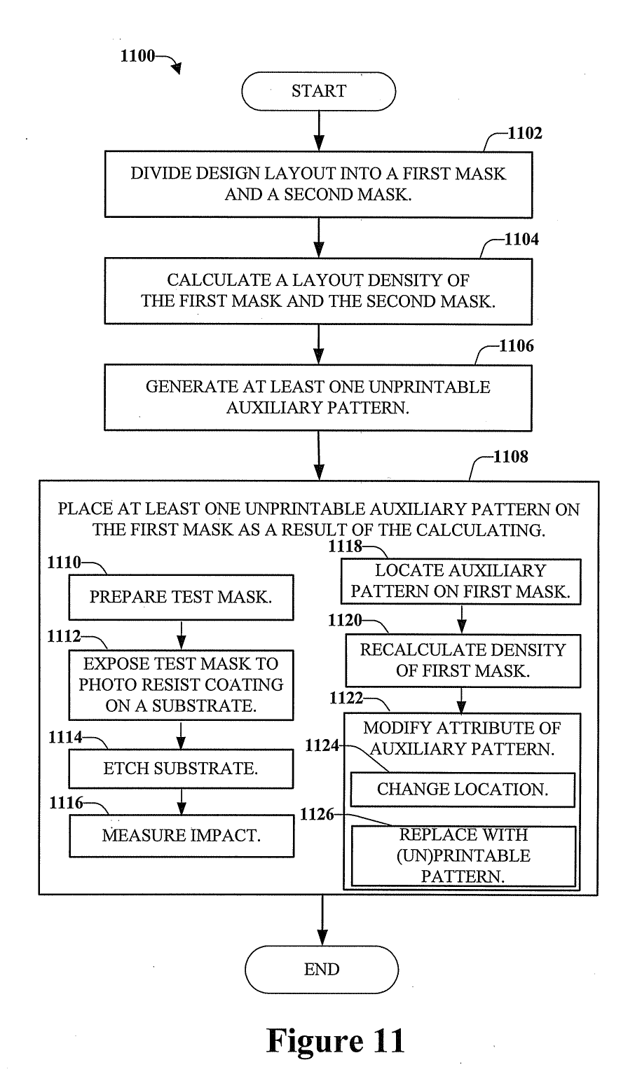

FIG. 11 illustrates a further non-limiting example method 1100 for the generation of additional shapes on a photomask for a multiple exposure process, according to an aspect. Method 1100 starts, at 1102, by dividing a design layout into a first mask and at least a second mask. The layout density of each of the first mask and the at least a second mask is calculated, at 1104. The calculation of the density of each mask can be performed independently, according to an aspect. At 1106, at least one unprintable auxiliary pattern is generated and, at 1108, the at least one unprintable auxiliary pattern is placed on the first mask as a result of the calculation.

In accordance with some aspects, the placing comprises preparing, at 1110, a test mask that comprises patterns with a density variation. At 1112, the test mask is exposed to photo resist coating on a substrate. The substrate is etched, at 1114. An impact of a pattern size and a topography is measured, at 1116. Depending on the result of the measurement, one or more unprintable auxiliary patterns may be placed on the test mask and/or one or more unprintable auxiliary patterns might be removed from the test mask. Additionally or alternatively as a result of the measurement, one or more unprintable auxiliary patterns can be removed and replaced with one or more printable auxiliary patterns and/or one or more printable auxiliary patterns can be removed and replaced with one or more unprintable auxiliary patterns.

According to some aspects, the placing comprises locating, at 1118, the at least one unprintable auxiliary pattern into a large space on the first mask. At 1120, a density of the first mask is recalculated and, at 1122, an attribute of at least one of the unprintable auxiliary patterns is modified.

In an aspect, the modification can comprise changing a location of at least one of the unprintable auxiliary patterns, at 1124. According to another aspect, the modification can comprise, at 1126, replacing at least one unprintable auxiliary pattern with at least one printable auxiliary pattern and/or replacing a printable auxiliary pattern with an unprintable auxiliary pattern.

As disclosed herein, an aspect relates to a method for manufacturing a semiconductor device. The method can include employing at least one processor to facilitate execution of code instructions retained in at least one memory device, the at least one processor, in response to execution of the code instructions, causing a device to perform operations. The operations can include dividing a design layout into a first mask, a second mask, and a third mask and calculating a layout density of the first mask, the second mask, and the third mask. The operations can also include generating at least one unprintable auxiliary pattern and placing the at least one unprintable auxiliary pattern on the first mask as a result of the calculating. The at least one unprintable auxiliary pattern can overlap a main area of the second mask and the third mask.

In an implementation, generating at least one unprintable auxiliary pattern comprises generating two or more unprintable auxiliary patterns, wherein the two or more unprintable auxiliary patterns are a different size, a different shape, or both a different size and a different shape. In a further implementation, generating at least one unprintable auxiliary pattern comprises generating two or more unprintable auxiliary patterns, wherein the two or more unprintable auxiliary patterns comprise a similar size, a similar shape, or a similar size and a similar shape.

Calculating the layout density, according to an implementation, includes selecting a first area of the design layout and evaluating a density of the first area. Also included can be selecting a second area of the design layout and evaluating the density of the second area. Further, the method can include selecting a subsequent area of the design layout and evaluating the density of the subsequent area. In an aspect, selecting the second area can comprise shifting from the first area to a location that is offset from the first area by at least a portion of the first area.

In an implementation, placing the at least one unprintable auxiliary pattern can include preparing a test mask that comprises patterns with a density variation and exposing the test mask to photo resist coating on a substrate. The placement can also include etching the substrate and measuring an impact of a pattern size and a topography.

In another implementation placing the at least one unprintable auxiliary pattern can include locating the at least one unprintable auxiliary pattern into a large space on the first mask. The placement can also include recalculating a density of the first mask and modifying an attribute of one of the unprintable auxiliary patterns. Further to this implementation, the modifying can comprise at least one of: changing a location of the at least one unprintable auxiliary pattern, replacing the at least one unprintable auxiliary pattern with at least one printable auxiliary pattern, or replacing at least one printable auxiliary pattern with at least one unprintable auxiliary pattern.

In an implementation, a photomask can be prepared by the above method. In another implementation, a semiconductor device can comprise the photomask. The semiconductor device can be a large scale integrated circuit (LSI) device.

Another aspect relates to a system comprising a memory that stores computer executable components and a processor that executes the computer executable components stored in the memory. The computer executable components comprise a partition component that divides a wafer layout into at least two photomasks and a density component that determines a density of each of the at least two photomasks. The computer executable components can also comprise a develop component that creates unprintable auxiliary patterns as a function of the determined density of each of the at least two photomasks and a locate component that selectively places each of the unprintable auxiliary patterns on the at least two photomasks.

In an implementation, the develop component can create unprintable auxiliary patterns that are similar in size, similar in shape, or similar in both size and shape. In another implementation, the develop component creates unprintable auxiliary patterns that are different in size, different in shape, or different in both size and shape.

The system, in an implementation, further comprises a segment component that can divide each of the at least two photomasks into sections and an evaluation component that can independently calculate a density of each of the sections.

In another implementation, the system can further comprises a distribution component that can locate at least one auxiliary pattern into a larger space on one of the at least two photomasks. Further to this implementation, the density component can recalculate a density on the one photomask and the develop component can modify an attribute of at least one of the unprintable auxiliary patterns. Further to this implementation, the attribute can be one of: a location of the at least one unprintable auxiliary pattern, replacement of at least one unprintable auxiliary pattern with a printable auxiliary pattern, or replacement of at least one printable auxiliary pattern with an unprintable auxiliary pattern.

Yet another aspect relates to a non-transitory computer readable storage medium comprising computer executable instructions that, in response to execution, cause a computing system to perform operations. The operations can comprise dividing a design layout into a first mask and at least a second mask and calculating a layout density of the first mask and the second mask. The operations can also comprise generating at least one unprintable auxiliary pattern and placing the at least one unprintable auxiliary pattern on the first mask as a result of the calculating. The at least one unprintable auxiliary pattern can overlap a main area of at least the second mask.

In an implementation, generating at least one unprintable auxiliary pattern can comprise generating two or more unprintable auxiliary patterns, wherein the two or more unprintable auxiliary patterns are a different size, a different shape, or both a different size and a different shape. In another implementation, generating at least one unprintable auxiliary pattern can comprise generating two or more unprintable auxiliary patterns, wherein the two or more unprintable auxiliary patterns comprise a similar size, a similar shape, or a similar size and a similar shape.

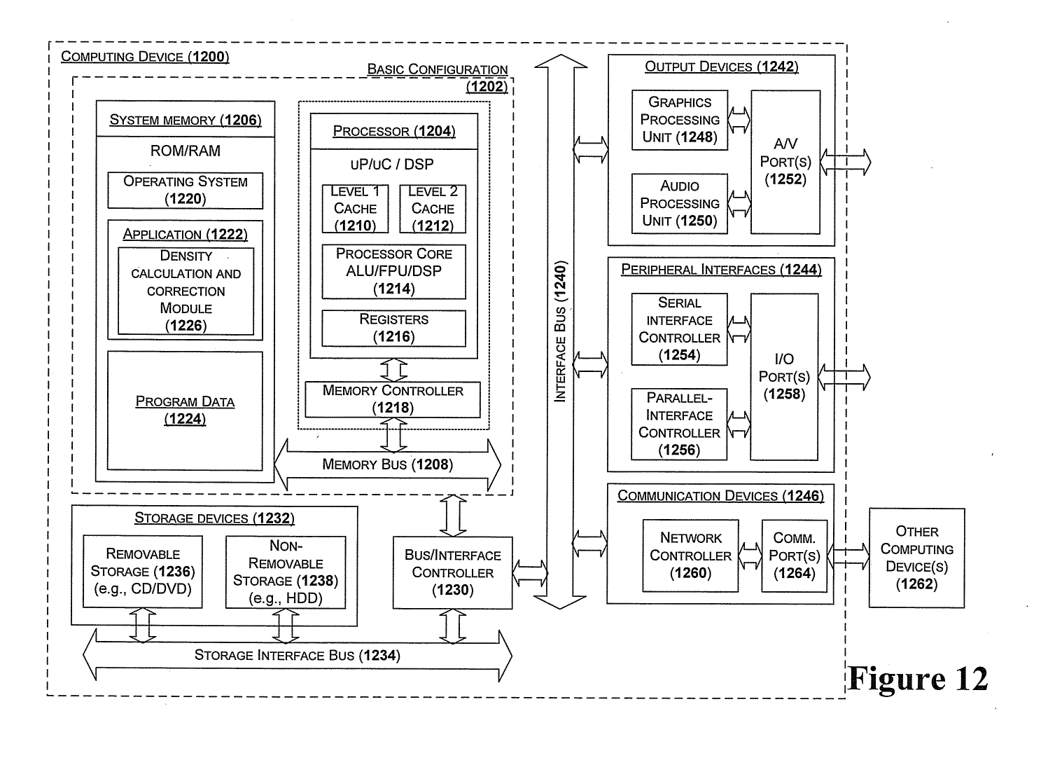

FIG. 12 is a block diagram illustrating an example computing device that is arranged for at least some of the embodiments disclosed herein. In a very basic configuration 1202, computing device 1200 comprises one or more processors 1204 and a system memory 1206. A memory bus 1208 can be used for communicating between processor 1204 and system memory 1206.

Depending on the desired configuration, processor 1204 can be of any type of processor including but not limited to a microprocessor (μP), a microcontroller (μC), a digital signal processor (DSP), or any combination thereof. Processor 1204 can include one more levels of caching, such as a level one cache 1210 and a level two cache 1212, a processor core 1214, and registers 1216. An example processor core 1214 can include an arithmetic logic unit (ALU), a floating point unit (FPU), a digital signal processing core (DSP Core), or any combination thereof. An example memory controller 1218 can also be used with processor 1204, or in some implementations memory controller 1218 can be an internal part of processor 1204.

Depending on the desired configuration, system memory 1206 can be of any type including but not limited to volatile memory (such as RAM), non-volatile memory (such as ROM, flash memory, etc.) or any combination thereof. System memory 1206 can include an operating system 1220, one or more applications 1222, and/or program data 1224. Application 1222 can include a density calculation and correction module 1226 that is arranged to perform the functions as described herein. Program data 1224 can include wafer density specification and resource information. In some embodiments, application 1222 can be arranged to operate with program data 1224 on operating system 1220.

Computing device 1200 can have additional features or functionality, and/or additional interfaces to facilitate communications between basic configuration 1202 and any other devices and interfaces. For example, a bus/interface controller 1230 can be used to facilitate communications between basic configuration 1202 and one or more data storage devices 1232 via a storage interface bus 1234. Data storage devices 1232 can be removable storage devices 1236, non-removable storage devices 1238, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media can include volatile and nonvolatile, removable and non-removable media implemented in any method or technology for storage of information, such as computer readable instructions, data structures, program modules, or other data.

System memory 1206, removable storage devices 1236 and non-removable storage devices 1238 are examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium that may be used to store the desired information and that may be accessed by computing device 1200.

Computing device 1200 can also include an interface bus 1240 for facilitating communication from various interface devices (e.g., output devices 1242, peripheral interfaces 1244, and communication devices 1246) to basic configuration 1202 via bus/interface controller 1230. Example output devices 1242 include a graphics processing unit 1248 and an audio processing unit 1250, which can be configured to communicate to various external devices such as a display or speakers via one or more A/V ports 1252. Example peripheral interfaces 1244 include a serial interface controller 1254 or a parallel interface controller 1256, which can be configured to communicate with external devices such as input devices (e.g., keyboard, mouse, pen, voice input device, touch input device, etc.) or other peripheral devices (e.g., printer, scanner, etc.) via one or more I/O ports 1258. An example communication device 1246 includes a network controller 1260, which can be arranged to facilitate communications with one or more other computing devices 1262 over a network communication link via one or more communication ports 1264.

The network communication link can be one example of a communication media. Computing devices typically include a variety of media, which can include computer-readable storage media or communications media, which two terms are used herein differently from one another as follows.

Computer-readable storage media can be any available storage media that can be accessed by the computer and includes both volatile and nonvolatile media, removable and non-removable media. By way of example, and not limitation, computer-readable storage media can be implemented in connection with any method or technology for storage of information such as computer-readable instructions, program modules, structured data, or unstructured data. Computer-readable storage media can include, but are not limited to, RAM, ROM, EEPROM, flash memory or other memory technology, CD-ROM, digital versatile disk (DVD) or other optical disk storage, magnetic cassettes, magnetic tape, magnetic disk storage or other magnetic storage devices, or other tangible and/or non-transitory media which can be used to store desired information. Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media can include wired media, such as a wired network or direct-wired connection, and wireless media such as acoustic, radio frequency (RF), microwave, infrared (IR), and other wireless media. The term computer readable media as used herein can include both storage media and/or communication media.

Computing device 1200 can be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. Computing device 1200 can also be implemented as a controller in an industrial automation environment, a semiconductor processing facility, and/or as a personal computer.

With respect to any figure or numerical range for a given characteristic, a figure or a parameter from one range may be combined with another figure or a parameter from a different range for the same characteristic to generate a numerical range. All numbers, values, and/or expressions referring to quantities of ingredients, reaction conditions, and so forth used in the specification and claims are to be understood as modified in all instances by the term “about.”

What has been described above includes examples of systems and methods that provide advantages of the one or more aspects. It is, of course, not possible to describe every conceivable combination of components or methods for purposes of describing the aspects, but one of ordinary skill in the art may recognize that many further combinations and permutations of the claimed subject matter are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

As used in this application, the terms “component,” “system,” and the like are intended to refer to a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, a program, and/or a computer. By way of illustration, both an application running on a server or network controller, and the server or network controller can be a component. One or more components may reside within a process and/or thread of execution and a component may be localized on one computer and/or distributed between two or more computers. Also, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software, or firmware application executed by a processor, wherein the processor can be internal or external to the apparatus and executes at least a part of the software or firmware application. As yet another example, a component can be an apparatus that provides specific functionality through electronic components without mechanical parts, the electronic components can include a processor therein to execute software or firmware that confers at least in part the functionality of the electronic components. As further yet another example, interface(s) can include input/output (I/O) components as well as associated processor, application, or Application Programming Interface (API) components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form.

What is claimed is:

1. A method for manufacturing a semiconductor device, comprising:
employing at least one processor to facilitate execution of code instructions retained in at least one memory device, the at least one processor, in response to execution of the code instructions, causing a device to perform operations comprising:
dividing a design layout into a first mask, a second mask, and a third mask;
calculating a layout density of the first mask, the second mask, and the third mask;
generating at least one unprintable auxiliary pattern; and
placing the at least one unprintable auxiliary pattern on the first mask as a result of the calculating, wherein the at least one unprintable auxiliary pattern overlaps a main area of the second mask and the third mask.

2. The method of claim 1, wherein the generating comprises generating two or more unprintable auxiliary patterns, wherein the two or more unprintable auxiliary patterns are a different size, a different shape, or both a different size and a different shape.

3. The method of claim 1, wherein the generating comprises generating two or more unprintable auxiliary patterns, wherein the two or more unprintable auxiliary patterns comprise a similar size, a similar shape, or a similar size and a similar shape.

4. The method of claim 1, wherein the calculating comprises:
selecting a first area of the design layout;
evaluating a density of the first area;
selecting a second area of the design layout;
evaluating the density of the second area;
selecting a subsequent area of the design layout; and
evaluating the density of the subsequent area.

5. The method of claim 4, wherein the selecting the second area comprises shifting from the first area to a location that is offset from the first area by at least a portion of the first area.

6. The method of claim 1, wherein the placing comprising:
preparing a test mask that comprises patterns with a density variation;
exposing the test mask to photo resist coating on a substrate;
etching the substrate; and
measuring an impact of a pattern size and a topography.

7. The method of claim 1, wherein the placing comprising:
locating the at least one unprintable auxiliary pattern into a large space on the first mask;
recalculating a density of the first mask; and
modifying an attribute of one of the unprintable auxiliary patterns.

8. The method of claim 7, wherein the modifying comprises at least one of:
changing a location of the at least one unprintable auxiliary pattern;
replacing the at least one unprintable auxiliary pattern with at least one printable auxiliary pattern; or
replacing the at least one printable auxiliary pattern with at least one unprintable auxiliary pattern.

9. A photomask prepared by the method of claim 1.

10. A semiconductor device comprising the photomask of claim 9.

11. The semiconductor device of claim 10 is a large scale integrated circuit (LSI) device.

12. A system, comprising:
a memory that stores computer executable components; and
a processor that executes the following computer executable components stored in the memory:
a partition component that divides a wafer layout into at least two photomasks;
a density component that determines a density of each of the at least two photomasks;
a develop component that creates unprintable auxiliary patterns as a function of the determined density of each of the at least two photomasks; and
a locate component that selectively places each of the unprintable auxiliary patterns on the at least two photomasks.

13. The system of claim 12, wherein the develop component creates unprintable auxiliary patterns that are similar in size, similar in shape, or similar in both size and shape.

14. The system of claim 12, wherein the develop component creates unprintable auxiliary patterns that are different in size, different in shape, or different in both size and shape.

15. The system of claim 12, further comprising:
a segment component that divides each of the at least two photomasks into sections; and
an evaluation component that independently calculations a density of each of the sections.

16. The system of claim 12, further comprising a distribution component that locates at least one auxiliary pattern into a larger space on one of the at least two photomasks, the density component recalculates a density on the one photomask and the develop component modifies an attribute of at least one of the unprintable auxiliary patterns.

17. The system of claim 16, wherein the attribute is one of: a location of the at least one unprintable auxiliary pattern, replacement of at least one unprintable auxiliary pattern with a printable auxiliary pattern, or replacement of at least one printable auxiliary pattern with an unprintable auxiliary pattern.

18. A non-transitory computer readable storage medium comprising computer executable instructions that, in response to execution, cause a computing system to perform operations, comprising:
dividing a design layout into a first mask and at least a second mask;
calculating a layout density of the first mask and at least the second mask;
generating at least one unprintable auxiliary pattern; and
placing the at least one unprintable auxiliary pattern on the first mask as a result of the calculating, wherein the at least one unprintable auxiliary pattern overlaps a main area of at least the second mask.

19. The non-transitory computer readable storage medium of claim 18, wherein the generating comprises generating two or more unprintable auxiliary patterns, wherein the two or more unprintable auxiliary patterns are a different size, a different shape, or both a different size and a different shape.

20. The non-transitory computer readable storage medium of claim 18, wherein the generating comprises generating two or more unprintable auxiliary patterns, wherein the two or more unprintable auxiliary patterns comprise a similar size, a similar shape, or a similar size and a similar shape.
